(19) United States
(12) Patent Application Publication
(10) Pub. No.: US 2017/0092697 A1
(43) Pub. Date: Mar. 30, 2017

(54) Oxide Electron Selective Layers

(71) Applicant: International Business Machines Corporation, Armonk, NY (US)

(72) Inventors: Liang-yi Chang, Hsinchu City (TW); Supratik Guha, Chicago, IL (US); Teodor K. Todorov, Yorktown Heights, NY (US)

(21) Appl. No.: 14/866,108

(22) Filed: Sep. 25, 2015

(51) Int. Cl. H01L 27/30; H01L 51/44; H01L 51/00; H01L 51/42

(52) U.S. Cl. CPC H01L 27/302; H01L 51/4213; H01L 51/442; H01L 51/0096; H01L 2251/308; H01L 2251/303; H01L 2251/301; H01L 51/0047; H01L 51/0037

(57) ABSTRACT

Oxide electron selective contacts for perovskite solar cells are provided. In one aspect, a method of forming a perovskite solar cell is provided. The method includes the steps of: depositing a layer of a hole transporting material on a substrate; forming a perovskite absorber on the hole transporting material; depositing an oxide electron transporting material on the perovskite absorber; and forming a top electrode on the oxide electron transporting material. Perovskite solar cells and tandem photovoltaic devices are also provided.

### FIELD OF THE INVENTION

The present invention relates to perovskite solar cells and more particularly, to improved electron-selective contacts for perovskite solar cells which provide an added benefit of protection against environmental humidity.

### BACKGROUND OF THE INVENTION

Wide-gap oxides such as titanium oxide (TiO₂) and zinc oxide (ZnO) are commonly used as electron-selective or hole-blocking layers in perovskite solar cells. However, the high processing temperatures required for device-quality TiO₂ layers and the deterioration of ZnO-perovskite assemblies at temperatures less than 80° C. (e.g., at a temperature of from about 50° C. to about 80° C.) limit use of these materials to very specific applications.

In particular, TiO₂ is an appropriate choice for a bottom contact on substrates with high temperature stability such as fluorine-doped tin oxide (FTO) coated glass, but not as a top contact or on plastic substrates or top devices in monolithic tandem solar cells where the bottom device has low temperature stability. ZnO is suitable for low-temperature perovskite fabrication processes and can only facilitate complete solar cells that do not exceed temperatures of 50° C.-80° C. at any time.

Therefore, alternative electron-selective contact materials for perovskite solar cells which are not subject to the above processing temperature constraints would be desirable.

### SUMMARY OF THE INVENTION

The present invention provides oxide electron selective contacts for perovskite solar cells. In one aspect of the invention, a method of forming a perovskite solar cell is provided. The method includes the steps of: depositing a layer of a hole transporting material on a substrate; forming a perovskite absorber on the hole transporting material; depositing an oxide electron transporting material on the perovskite absorber; and forming a top electrode on the oxide electron transporting material.

In another aspect of the invention, a perovskite solar cell is provided. The perovskite solar cell includes: a substrate; a layer of a hole transporting material on the substrate; a perovskite absorber on the hole transporting material; an oxide electron transporting material on the perovskite absorber; and a top electrode on the oxide electron transporting material.

In yet another aspect of the invention, a tandem photovoltaic device is provided. The tandem photovoltaic device includes: a chalcogenide-based bottom cell; and a perovskite-based top cell on the chalcogenide-based bottom cell. The perovskite-based top cell includes: a layer of a hole transporting material; a perovskite absorber on the hole transporting material; an oxide electron transporting material on the perovskite absorber; and a top electrode on the oxide electron transporting material.

A more complete understanding of the present invention, as well as further features and advantages of the present invention, will be obtained by reference to the following detailed description and drawings.

### BRIEF DESCRIPTION OF THE DRAWINGS

FIG. 1 is a diagram illustrating an exemplary methodology for forming a perovskite solar cell according to an embodiment of the present invention;

FIG. 2 is a diagram illustrating an exemplary perovskite solar cell formed using the method of FIG. 1 according to an embodiment of the present invention;

FIG. 3 is a diagram illustrating an exemplary tandem kesterite-perovskite photovoltaic device formed using the method of FIG. 1 according to an embodiment of the present invention;

FIG. 4 is a diagram illustrating an exemplary perovskite solar cell wherein the electron transporting material includes multiple layers according to an embodiment of the present invention;

FIG. 5 is a diagram illustrating samples used to assess the effects of the present oxide carrier selective material on device performance according to an embodiment of the present invention;

FIG. 6A is a diagram illustrating a first one of the samples which is a perovskite solar cell where such as phenyl-C61-butyric acid methyl ester (PCBM) is used as the only electron transporting material in the device according to an embodiment of the present invention;

FIG. 6B is a diagram illustrating a second one of the samples which is a perovskite solar cell where no electron transporting (n-type) layer is used according to an embodiment of the present invention;

FIG. 6C is a diagram illustrating a third one of the samples which is a perovskite solar cell where the present oxide carrier selective material is used as the sole electron transporting material in the device according to an embodiment of the present invention;

FIG. 6D is a diagram illustrating a fourth one of the samples which is a perovskite solar cell where a combination of electron transporting materials is employed, but the combination does not include the present oxide carrier selective material according to an embodiment of the present invention; and

FIG. 6E is a diagram illustrating a fifth one of the samples which is a perovskite solar cell where a combination of electron transporting materials is employed and includes the present oxide carrier selective material according to an embodiment of the present invention.

### DETAILED DESCRIPTION OF PREFERRED EMBODIMENTS

Provided herein are improved electron-selective contacts for perovskite solar cells formed from metal oxide layers of cerium (Ce) and other lanthanide metals, as well as oxides of transition metals, such as niobium (Nb), yttrium (Y), and hafnium (Hf). An additional benefit of metal oxides such as cerium oxide CeO₂-x, where 0<x<1 is oxygen and water scavenging properties. See, for example, N. Shehata et al., “Control of oxygen vacancies and Ce⁺³ concentrations in doped ceria nanoparticles via the selection of lanthanide element,” J. Nanopart. Res. (September 2012) 14:1173. These oxygen and water scavenging properties can benefit long-term device stability. See below. As will be described in detail below, the present metal oxide contacts can be used either as a sole n-selective layer in a perovskite solar cell, or in combination with other n-type materials such as phenyl-C61-butyric acid methyl ester (PCBM).

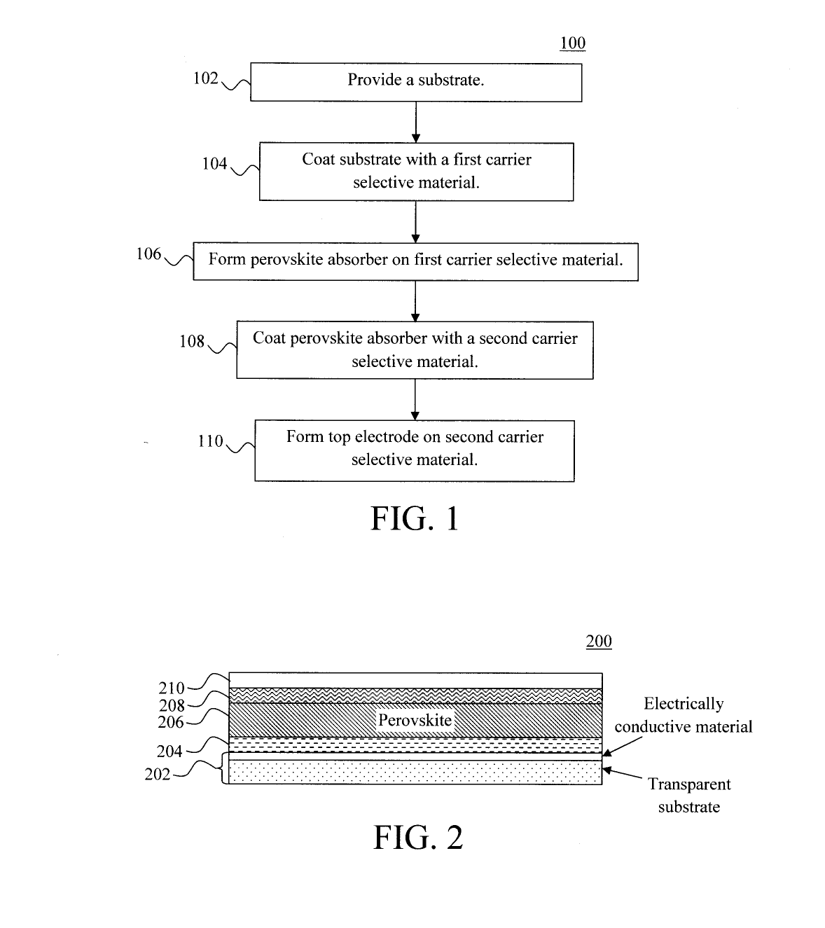

An overview of the present techniques is now provided by way of reference to FIG. 1 which provides an exemplary methodology 100 for forming a perovskite solar cell. The process begins in step 102 with a suitable substrate on which the solar cell will be constructed.

According to one exemplary embodiment, the substrate is a transparent substrate. Suitable transparent substrates include, but are not limited to, glass, quartz, or sapphire substrates. These transparent substrate materials are not electrically conductive. Thus, it may be desirable to coat the transparent substrate with a layer of an electrically conductive material, such as indium-tin-oxide (ITO), to serve as a bottom electrode of the device. ITO may be deposited onto the substrate using a process such as electron-beam (e-beam) evaporation or sputtering.

Alternatively, according to another exemplary embodiment, the starting substrate is a solar cell. This would be the case, for example, when a tandem photovoltaic device is being formed. For instance, a tandem photovoltaic device can include a chalcogenide-based bottom cell (e.g., a copper-indium-gallium-sulfur/selenium (CIGS) or kesterite-based bottom cell) and a perovskite-based top cell. See, for example, U.S. patent application Ser. No. 14/449,486 by Gershon et al., entitled “Tandem Kesterite-Perovskite Photovoltaic Device,” (hereinafter “U.S. patent application Ser. No. 14/449,486”), the contents of which are incorporated by reference as if fully set forth herein. As described in U.S. patent application Ser. No. 14/449,486, an exemplary tandem photovoltaic device configuration includes a kesterite (e.g., copper-zinc-tin-sulfur/selenium (commonly abbreviated as CZTS/Se))-based bottom cell and a perovskite-based top cell. In that case, the starting ‘substrate’ in instant methodology 100 would be the kesterite-based bottom cell. As provided above, in addition to a kesterite-based bottom cell, the tandem photovoltaic device can more generally include any type of chalcogenide-based bottom cell—such as a CIGS-based bottom cell.

Techniques for forming a kesterite-based bottom cell are provided in U.S. patent application Ser. No. 14/449,486. For example, beginning with a suitable substrate (e.g., a substrate coated with an electrically-conductive material), a CZT(S,Se) absorber layer is first formed on the substrate. A buffer layer is then formed on the absorber layer, followed by a transparent contact. In the tandem device configuration, the transparent contact can serve as both the top electrode of the CZT(S,Se) bottom cell and the bottom electrode of the perovskite-based top cell.

In step 104, the substrate is coated with a layer of a first carrier selective material. The term “carrier selective material” as used herein refers to either a hole transporting (p-type) or electron transporting (n-type) material. According to an exemplary embodiment, in step 104 the substrate is coated with a layer of a hole transporting material. Suitable hole transporting materials include, but are not limited to, poly(3,4-ethylenedioxythiophene) (PEDOT), poly(3,4-ethylenedioxythiophene)-poly(styrenesulfonate) (PEDOT:PSS), molybdenum trioxide (MoO₃), and combinations thereof. These hole transporting materials can be deposited from solution using a casting process such as spin-coating.

Next, in step 106, a perovskite absorber is formed on the first carrier selective material. The term “perovskite” as used herein refers to materials with a perovskite structure and the general formula ABX₃ (e.g., wherein A=CH₃NH₃ or NH=CHNH₃, B=lead (Pb) or tin (Sn), and X=chlorine (Cl) or bromine (Br) or iodine (I)). The perovskite structure is described and depicted, for example, in U.S. Pat. No. 6,429,318 B1 issued to Mitzi, entitled “Layered Organic-Inorganic Perovskites Having Metal-Deficient Inorganic Frameworks” (hereinafter “U.S. Pat. No. 6,429,318 B1”), the contents of which are incorporated by reference as if fully set forth herein. As described in U.S. Pat. No. 6,429,318 B1, perovskites generally have an ABX₃ structure with a three-dimensional network of corner-sharing BX₆ octahedra, wherein the B component is a metal cation that can adopt an octahedral coordination of X anions, and the A component is a cation located in the 12-fold coordinated holes between the BX₆ octahedra. The A component can be an organic or inorganic cation. See, for example, FIGS. 1a and 1b of U.S. Pat. No. 6,429,318 B1.

According to an exemplary embodiment, the perovskite absorber is formed in step 106 using the techniques described in U.S. patent application Ser. No. 14/449,486. For instance, the perovskite absorber may be formed by coating the substrate (or other layer on which the perovskite absorber is to be formed) with a metal halide layer MX₂, wherein M is at least one of lead (Pb) and tin (Sn), and X is at least one of fluorine (F), chlorine (Cl), bromine (Br), and iodine (I). A source of methylammonium halide is placed in close proximity to the substrate. The metal halide layer is then vacuum-annealed in the presence of the methylammonium halide source to form the perovskite on the substrate. Optical properties of the material can be monitored in real-time to observe formation of the perovskite. See U.S. patent application Ser. No. 14/449,486.

In step 108, the perovskite absorber is coated with a layer of a second carrier selective material. According to an exemplary embodiment, the first carrier selective material is a hole transporting material (see step 104), and the second carrier selective material is an electron transporting material.

According to the present techniques, the electron transporting material is a metal oxide selected from the group including, but not limited to, lanthanum oxide, cerium oxide, praseodymium oxide, neodymium oxide, promethium oxide, samarium oxide, europium oxide, gadolinium oxide, terbium oxide, dysprosium oxide, holmium oxide, erbium oxide, thulium oxide, ytterbium oxide, lutetium oxide, niobium oxide, yttrium oxide, hafnium oxide, and combinations thereof. The metal oxide may be used alone or in combination with one or more other electron transporting materials, such as phenyl-C61-butyric acid methyl ester (PCBM), C60, and/or bathocuproine (BCP). Examples employing the present oxide carrier selective material both as the sole electron transporting material and in combination with other electron transporting materials are described below.

According to an exemplary embodiment, the second carrier selective material is cerium oxide which is deposited onto the perovskite absorber using thermal evaporation. Thermal evaporation is preferred as it allows for deposition at low substrate temperatures (e.g., from about 900° C. to about 1,400° C., and ranges therebetween) without harming sensitive layers. Further, as highlighted above, an additional benefit of metal oxides such as cerium oxide CeO₂-x, where 0<x<1 is oxygen and water scavenging properties. Thermal evaporation does not require sophisticated equipment with an additional oxygen (O₂) source. Concomitantly, oxygen deficiency induced by this method can benefit the electronic properties and oxygen and water scavenging abilities of the material. For a discussion of the oxygen scavenging properties of cerium oxide see, for example, Imagawa et al., “Monodisperse CeO₂ Nanoparticles and Their Oxygen Storage and Release Properties,” J. Phys. Chem. C, January 2011, 115(3), pp. 1740-1745, the contents of which are incorporated by reference as if fully set forth herein. For a discussion of the water scavenging properties of cerium oxide see, for example, U.S. Patent Application Publication Number 2012/0302372 by Ricci et al., the contents of which are incorporated by reference as if fully set forth herein. The oxygen scavenging capability can be enhanced by forming oxygen deficient material CeO₂-x which is commonly formed when the material is deposited by thermal evaporation techniques due to partial decomposition of CeO₂ in vacuum.

In step 110, a top electrode of the device is formed on the second carrier selective material. The top electrode can be transparent. For solar cells, the top electrode and/or the bottom electrode has to be at least partially transparent in the solar spectrum. In the example provided above, ITO is employed as the bottom electrode. ITO is partially transparent in the solar spectrum. As compared to the bottom electrode, the top electrode is preferably formed from a lower work function material such as aluminum (Al) or magnesium (Mg). The top electrode material can be deposited onto the second carrier selective material using a physical vapor deposition process such as e-beam evaporation or sputtering. Alternatively, the top electrode can be formed from a transparent conductive contact, such as an evaporated transparent conductive oxide (TCO), such as ITO, or a nano-structured material, such as a silver nanowire mesh (wherein the mesh structure permits light to pass).

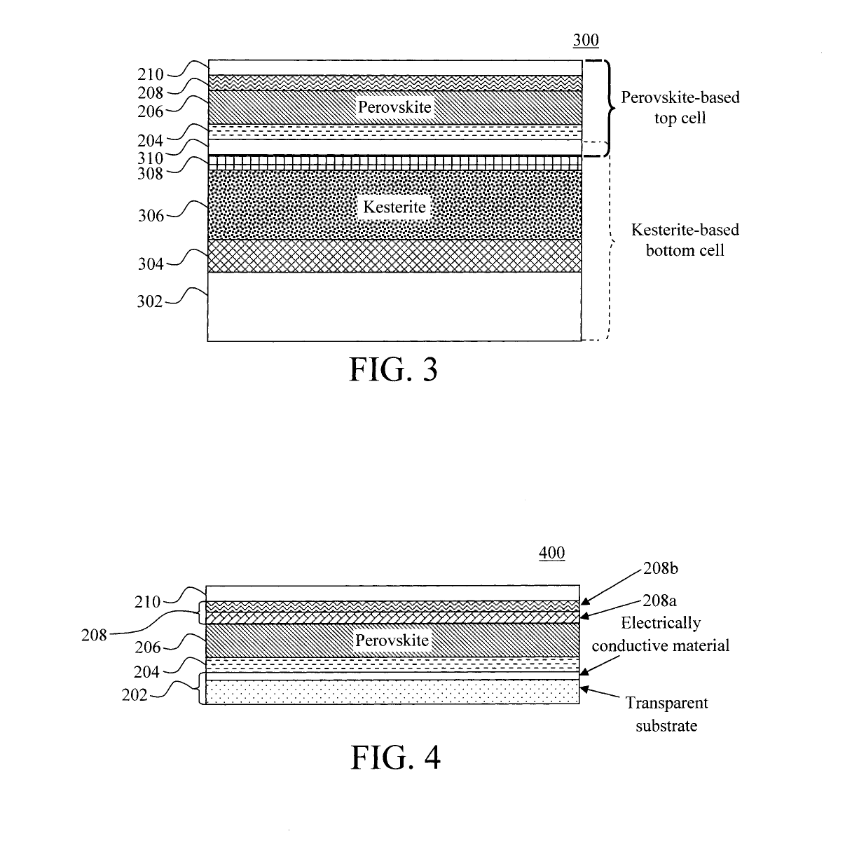

An exemplary perovskite solar cell 200 and tandem chalcogenide (e.g., kesterite)-perovskite photovoltaic device 300 produced according to methodology 100 are shown in FIG. 2 and FIG. 3, respectively. Namely, as shown in FIG. 2, the solar cell 200 includes a substrate 202, a first carrier selective material 204 on the substrate 202, a perovskite absorber 206 on the first carrier selective material 204, a second carrier selective material 208 on the perovskite absorber 206, and a top electrode 210 on the second carrier selective material 208.

As provided above, the substrate 202 can be a transparent substrate, such as a glass, quartz, or sapphire substrate which may optionally be coated with a layer of an electrically conductive material, such as ITO, to serve as a bottom electrode of the device. See description of step 102 of methodology 100 above.

According to an exemplary embodiment, the first carrier selective material 204 is a hole transporting material, and the second carrier selective material 208 is an electron transporting material. As provided above, suitable hole transporting materials include, but are not limited to PEDOT:PSS and/or MoO₃. See description of step 104 of methodology 100 above.

As provided above, the perovskite absorber 206 is formed from a material having a perovskite structure and the general formula ABX₃ (e.g., wherein A=CH₃NH₃ or NH=CHNH₃, B=Pb or Sn, and X=Cl, Br or I). See description of step 106 of methodology 100 above.

According to the present techniques, the electron transporting material is a metal oxide selected from the group including, but not limited, lanthanum oxide, cerium oxide, praseodymium oxide, neodymium oxide, promethium oxide, samarium oxide, europium oxide, gadolinium oxide, terbium oxide, dysprosium oxide, holmium oxide, erbium oxide, thulium oxide, ytterbium oxide, lutetium oxide, niobium oxide, yttrium oxide, hafnium oxide, and combinations thereof. See description of step 108 of methodology 100 above. The metal oxide may be used as the sole electron transporting material, or combined with one or more other electron transporting materials such as PCBM, C60, and/or BCP. For instance, it has been found that device performance can be enhanced by combining the present oxide carrier selective material with a layer of PCBM.

Finally, as provided above, the top electrode 210 can be formed from a metal such as Al or Mg, or from a transparent conductive material, such as a TCO (e.g., ITO) or a nano-structured material (e.g., a silver nanowire mesh). See description of step 110 of methodology 100 above.

With a tandem photovoltaic device configuration, the ‘substrate’ on which the perovskite solar cell is built is actually a bottom cell—such as a chalcogenide-based bottom cell. An exemplary tandem chalcogenide-perovskite photovoltaic device 300 is shown illustrated in FIG. 3.

In the example shown in FIG. 3, the kesterite-based bottom cell includes a substrate 302, a layer of an electrically conductive material 304 on the substrate 302, a chalcogenide absorber layer 306 on the electrically conductive material 304, a buffer layer 308 on the chalcogenide absorber layer 306, and a transparent contact 310 on the buffer layer 308.

By way of example only, the substrate 302 can be formed from a transparent material, such as glass, quartz, or sapphire. The layer of electrically conductive material 304 may include a TCO such as ITO. The layer of electrically conductive material 304 will serve as a bottom electrode of the kesterite-based bottom cell. The transparent contact 310 will serve as a top electrode of the kesterite-based bottom cell. Thus, while the perovskite-based top cell in this example has the same general configuration as in FIG. 2 (wherein the same structures are numbered alike), instead of having a separate substrate 202 the substrate here is the chalcogenide-based bottom cell with its top-most layer (i.e., transparent contact 310) being the first layer in the perovskite-based top cell. The transparent contact 310 may be formed from a TCO, such as ITO or aluminum-doped zinc oxide (AZO).

According to an exemplary embodiment, the chalcogenide absorber layer 306 is a kesterite material. As provided above, a kesterite material contains copper (Cu), zinc (Zn), and tin (Sn), and one or more of sulfur (S) and/or selenium (Se), commonly abbreviated as CZT(S,Se). The present techniques are not however limited to tandem device configurations with CZT(S,Se) kesterite-based bottom cells. For instance, tandem photovoltaic devices may also be fabricated in the same manner described herein based on CIGS-based bottom cells. As is known in the art, CIGS commonly refers to an alloy material containing Cu, indium (In), gallium, and one or more of S and Se. See, for example, R. F. Service, “Perovskite Solar Cells Keep On Surging,” Science, volume 344, no. 6183, pg. 458 (May 2014), the contents of which are incorporated by reference as if fully set forth herein.

As provided above, the present oxide carrier selective material may be used as the sole electron transporting material in the device (i.e., the second carrier selective material 208 in FIG. 2 and FIG. 3 includes only the present oxide electron transporting material, e.g., CeO₂) or, alternatively, it may be used in combination with one or more other electron transporting materials—such as PCBM, C60, and/or BCP. FIG. 4 is a diagram illustrating an exemplary perovskite solar cell 400, wherein the second carrier selective material 208 includes multiple layers. Specifically, as shown in FIG. 4 the second carrier selective material 208 has a multilayer configuration including a first layer 208a, a second layer 208b, etc. at least one of which is formed from the present oxide carrier selective material. By way of example only, layer 208a could be formed from PCBM, C60, and/or BCP, and layer 208b can be formed from the present oxide carrier selective material. This same multilayer configuration of the second carrier selective material 208 may be employed in any of the device structures described herein, including the tandem photovoltaic device of FIG. 3.

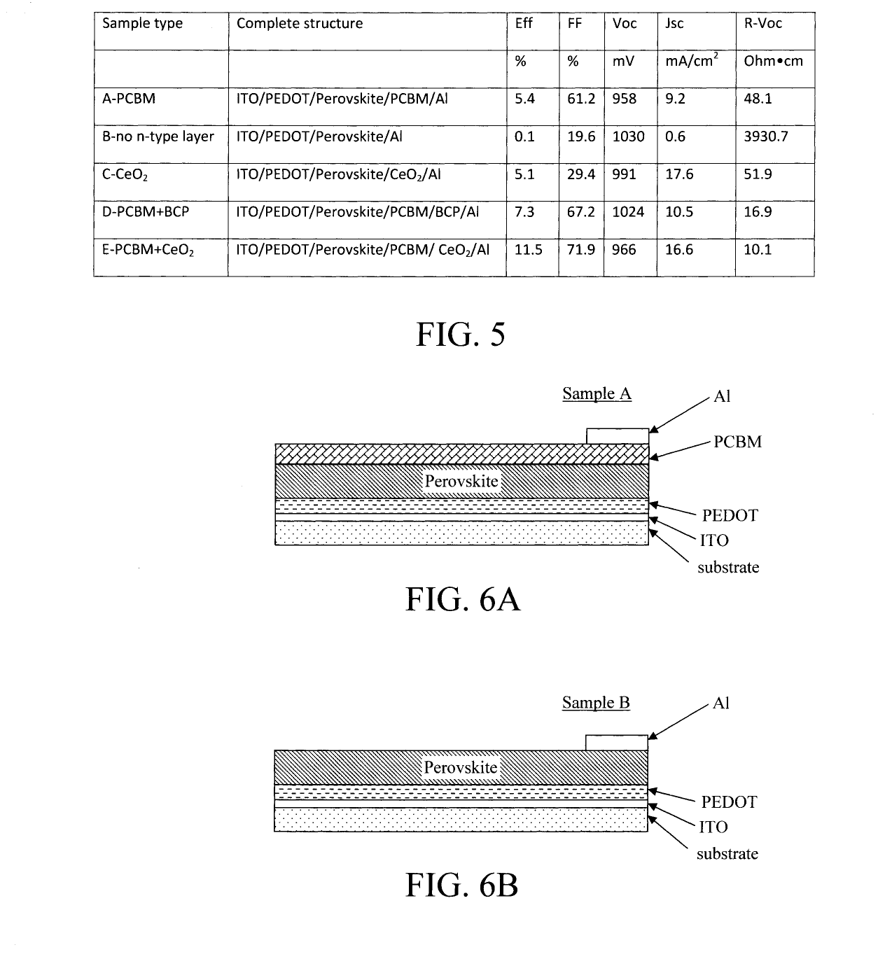

The present techniques are further described by way of reference to the following non-limiting examples. In order to assess the effects of the the present oxide carrier selective material on device performance, several different device configurations were tested, some with and some without the oxide carrier selective material. A summary of the devices tested is presented in FIG. 5. Five different device configurations were prepared (samples A-E)—see column labeled “Sample type.” In the first sample A, PCBM was used as the only electron transporting material in the device. Specifically, the device in sample A included an ITO coated substrate (i.e., ITO serves as the bottom electrode), PEDOT as a hole transporting material on the substrate, a perovskite absorber on the PEDOT layer, PCBM as an electron transporting material on the perovskite absorber, and an aluminum (Al) top electrode. The first sample A had an efficiency (Eff) of 5.4%, a fill factor (FF) of 61.2%, an open current voltage (Voc) of 958 millivolts (mV), a short circuit current (Jsc) of 9.2 milliamps per square centimeter (mA/cm²), and a resistance (R-Voc) of 48.1 ohm centimeter (ohm·cm).

In the second sample B, no electron transporting (n-type) layer was used. Specifically, the device in sample B included an ITO coated substrate (i.e., ITO serves as the bottom electrode), PEDOT as a hole transporting (p-type) material on the substrate, a perovskite absorber on the PEDOT layer, and an Al top electrode. The second sample B had an Eff of 0.1%, a FF of 19.6%, a Voc of 1030 mV, a Jsc of 0.6 mA/cm², and a R-Voc of 3930.7 ohm·cm. Thus as compared with sample A, sample B having no electron transporting material exhibits a significant decrease in efficiency.

In the third sample C, the present oxide carrier selective material (in this case CeO₂) was used as the sole electron transporting material in the device. Specifically, the device in sample C included an ITO coated substrate (i.e., ITO serves as the bottom electrode), PEDOT as a hole transporting material on the substrate, a perovskite absorber on the PEDOT layer, CeO₂ as an electron transporting material on the perovskite absorber, and an Al top electrode. The third sample C had an Eff of 5.1%, a FF of 29.4%, a Voc of 991 mV, a Jsc of 17.6 mA/cm², and a R-Voc of 51.9 ohm·cm. Thus as compared with sample A and sample B, sample C shows that CeO₂ is a viable substitute for PCBM as the electron transporting material (i.e., sample C shows an efficiency comparable with sample A, which is greatly above that of sample B).

In the fourth sample D, a combination of electron transporting materials was employed, but the combination did not include the present oxide carrier selective material. Specifically, the device in sample D included an ITO coated substrate (i.e., ITO serves as the bottom electrode), PEDOT as a hole transporting material on the substrate, a perovskite absorber on the PEDOT layer, a layer of PCBM and a layer of BCP as a combination of electron transporting materials on the perovskite absorber, and an Al top electrode. The fourth sample D had an Eff of 7.3%, a FF of 67.2%, a Voc of 1024 mV, a Jsc of 10.5 mA/cm², and a R-Voc of 16.9 ohm·cm. Thus as compared with sample A, sample D shows that by combining different electron transporting materials, one can achieve a higher efficiency device.

In the fifth sample E, a combination of electron transporting materials was employed including the present oxide carrier selective material. Specifically, the device in sample E included an ITO coated substrate (i.e., ITO serves as the bottom electrode), PEDOT as a hole transporting material on the substrate, a perovskite absorber on the PEDOT layer, a layer of PCBM and a layer of CeO₂ as a combination of electron transporting materials on the perovskite absorber, and an Al top electrode. The fifth sample E had an Eff of 11.5%, a FF of 71.9%, a Voc of 966 mV, a Jsc of 16.6 mA/cm², and a R-Voc of 10.1 ohm·cm. Thus as compared with sample D, sample E shows that by including the present oxide carrier selective material in a multilayer electron transporting material the highest efficiency devices are produced.

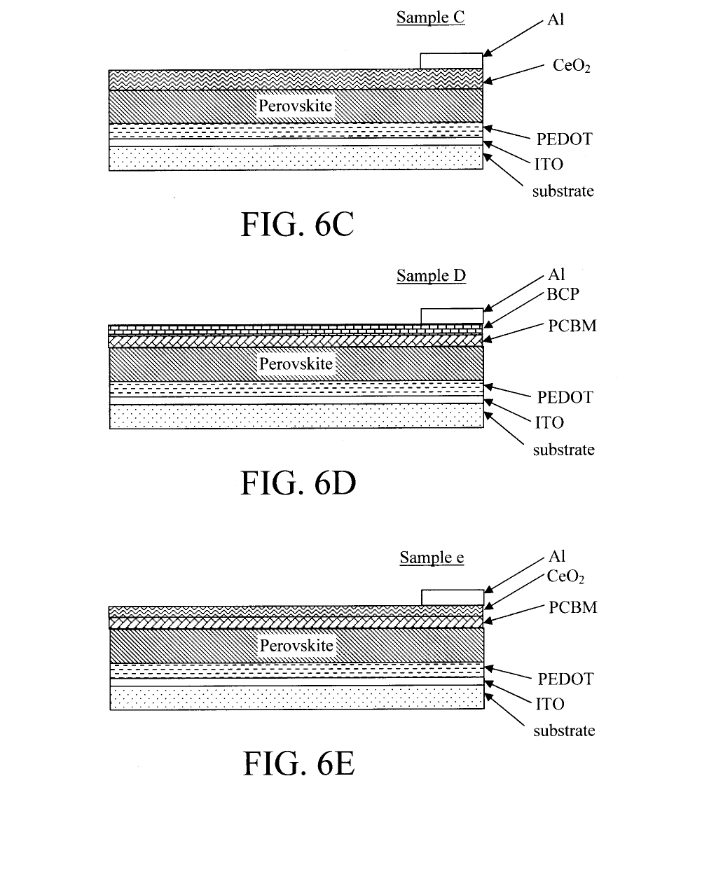

FIGS. 6A-E are diagrams illustrating the device structures of samples A-E (of FIG. 5), respectively. Specifically, FIG. 6A shows a perovskite solar cell where PCBM is used as the only electron transporting material in the device. Specifically, as shown in FIG. 6A, the device has an ITO coated substrate (i.e., ITO serves as the bottom electrode), PEDOT as a hole transporting material on the substrate, a perovskite absorber on the PEDOT layer, PCBM as an electron transporting material on the perovskite absorber, and an Al top electrode.

As shown in FIGS. 6A-E, the top electrode does not have to fully cover the top surface of the device. This permits light to pass through to the photoactive layers of the device. As provided above, a TCO, such as ITO or AZO, or a nanostructured material, such as a silver nanowire mesh, are suitable alternatives for the top electrode, especially in the case of a tandem device configuration where shadowing effects must be minimized since light has to reach the bottom cell.

FIG. 6B shows a perovskite solar cell where no electron transporting (n-type) layer is used. Specifically, as shown in FIG. 6B, the device has an ITO coated substrate (i.e., ITO serves as the bottom electrode), PEDOT as a hole transporting (p-type) material on the substrate, a perovskite absorber on the PEDOT layer, and an Al top electrode.

FIG. 6C shows a perovskite solar cell where the present oxide carrier selective material (in this case CeO₂) is used as the sole electron transporting material in the device. Specifically, as shown in FIG. 6C, the device has an ITO coated substrate (i.e., ITO serves as the bottom electrode), PEDOT as a hole transporting material on the substrate, a perovskite absorber on the PEDOT layer, CeO₂ as an electron transporting material on the perovskite absorber, and an Al top electrode.

FIG. 6D shows a perovskite solar cell where a combination of electron transporting materials is employed, but the combination does not include the present oxide carrier selective material. Specifically, as shown in FIG. 6D, the device has an ITO coated substrate (i.e., ITO serves as the bottom electrode), PEDOT as a hole transporting material on the substrate, a perovskite absorber on the PEDOT layer, a layer of PCBM and a layer of BCP as a combination of electron transporting materials on the perovskite absorber, and an Al top electrode.

FIG. 6E shows a perovskite solar cell where a combination of electron transporting materials is employed and includes the present oxide carrier selective material. Specifically, as shown in FIG. 6B, the device has an ITO coated substrate (i.e., ITO serves as the bottom electrode), PEDOT as a hole transporting material on the substrate, a perovskite absorber on the PEDOT layer, a layer of PCBM and a layer of CeO₂ as a combination of electron transporting materials on the perovskite absorber, and an Al top electrode.

Although illustrative embodiments of the present invention have been described herein, it is to be understood that the invention is not limited to those precise embodiments, and that various other changes and modifications may be made by one skilled in the art without departing from the scope of the invention.

What is claimed is:

1. A method of forming a perovskite solar cell, comprising the steps of
depositing a layer of a hole transporting material on a substrate;
forming a perovskite absorber on the hole transporting material;
depositing an oxide electron transporting material on the perovskite absorber; and
forming a top electrode on the oxide electron transporting material.

2. The method of claim 1, wherein the substrate comprises a transparent substrate coated with an electrically conductive material.

3. The method of claim 2, wherein the transparent substrate is formed from glass, quartz, or sapphire.

4. The method of claim 2, wherein the electrically conductive material comprises indium-tin-oxide (ITO).

5. The method of claim 1, wherein the substrate comprises a solar cell such that a tandem device is formed with the solar cell as a bottom cell and the perovskite solar cell as a top cell of the tandem device.

6. The method of claim 5, wherein the solar cell comprises a chalcogenide-based solar cell.

7. The method of claim 1, wherein the hole transporting material is selected from the group consisting of: poly(3,4-ethylenedioxythiophene) (PEDOT), poly(3,4-ethylenedioxythiophene)-poly(styrenesulfonate) (PEDOT:PSS), molybdenum trioxide (MoO₃), and combinations thereof.

8. The method of claim 1, wherein the oxide electron transporting material comprises a metal oxide selected from the group consisting of: lanthanum oxide, cerium oxide, praseodymium oxide, neodymium oxide, promethium oxide, samarium oxide, europium oxide, gadolinium oxide, terbium oxide, dysprosium oxide, holmium oxide, erbium oxide, thulium oxide, ytterbium oxide, lutetium oxide, niobium oxide, yttrium oxide, hafnium oxide, and combinations thereof.

9. The method of claim 1, wherein the electron transporting material comprises cerium oxide.

10. The method of claim 1, wherein the oxide electron transporting material is a sole electron transporting material in the perovskite solar cell.

11. The method of claim 1, further comprising the steps of:
depositing a first electron transporting material on the perovskite absorber; and
depositing a second electron transporting material on the first electron transporting material, wherein the second electron transporting material comprises the oxide electron transporting material.

12. The method of claim 11, wherein the second electron transporting material is selected from the group consisting of: phenyl-C61-butyric acid methyl ester (PCBM), C60, and bathocuproine (BCP).

13. The method of claim 1, wherein the top electrode comprises aluminum or magnesium.

14. The method of claim 1, wherein the top electrode comprises ITO or a nano-structured material.

15. A perovskite solar cell, comprising:
a substrate;
a layer of a hole transporting material on the substrate;
a perovskite absorber on the hole transporting material;
an oxide electron transporting material on the perovskite absorber; and
a top electrode on the oxide electron transporting material.

16. The perovskite solar cell of claim 15, wherein the oxide electron transporting material comprises a metal oxide selected from the group consisting of: lanthanum oxide, cerium oxide, praseodymium oxide, neodymium oxide, promethium oxide, samarium oxide, europium oxide, gadolinium oxide, terbium oxide, dysprosium oxide, holmium oxide, erbium oxide, thulium oxide, ytterbium oxide, lutetium oxide, niobium oxide, yttrium oxide, hafnium oxide, and combinations thereof.

17. The perovskite solar cell of claim 15, further comprising:
a first electron transporting material on the perovskite absorber; and
a second electron transporting material on the first electron transporting material, wherein the second electron transporting material comprises the oxide electron transporting material.

18. The perovskite solar cell of claim 17, wherein the second electron transporting material is selected from the group consisting of: PCBM, C60, and BCP.

19. A tandem photovoltaic device, comprising:
a chalcogenide-based bottom cell; and
a perovskite-based top cell on the chalcogenide-based bottom cell, the perovskite-based top cell comprising: a layer of a hole transporting material; a perovskite absorber on the hole transporting material; an oxide electron transporting material on the perovskite absorber; and a top electrode on the oxide electron transporting material.

20. The tandem photovoltaic device of claim 19, wherein the oxide electron transporting material comprises a metal oxide selected from the group consisting of: lanthanum oxide, cerium oxide, praseodymium oxide, neodymium oxide, promethium oxide, samarium oxide, europium oxide, gadolinium oxide, terbium oxide, dysprosium oxide, holmium oxide, erbium oxide, thulium oxide, ytterbium oxide, lutetium oxide, niobium oxide, yttrium oxide, hafnium oxide, and combinations thereof.
